(19) United States
(12) Patent Application Publication
(10) Pub. No.: US 2025/0006566 A1
(43) Pub. Date: Jan. 2, 2025

(54) SEMICONDUCTOR MODULE, POWER CONVERSION DEVICE, AND METHOD FOR MANUFACTURING SEMICONDUCTOR MODULE

(71) Applicant: HITACHI ASTEMO, LTD., Hitachinaka-shi, Ibaraki (JP)

(72) Inventors: Nobutake TSUYUNO, Tokyo (JP); Akira MIMA, Tokyo (JP); Yujiro KANEKO, Hitachinaka-shi (JP); Eiichi IDE, Tokyo (JP)

(73) Assignee: HITACHI ASTEMO, LTD., Hitachinaka-shi, Ibaraki (JP)

(21) Appl. No.: 18/712,774

(22) PCT Filed: Nov. 25, 2022
(86) PCT No.: PCT/JP2022/043610

§ 371 Date: May 23, 2024

(30) Foreign Application Priority Data
Nov. 30, 2021 (JP) 2021-194712

(51) Int. Cl. H01L 23/051; H01L 21/56; H01L 23/31; H01L 23/473; H01L 23/64; H01L 25/07; H01L 25/18; H02M 7/00

(52) U.S. Cl. CPC H01L 23/051; H01L 23/3121; H01L 23/3142; H01L 23/647; H01L 25/072; H01L 25/18; H02M 7/003; H01L 21/565; H01L 23/473

(57) ABSTRACT

A semiconductor module includes: a plurality of power semiconductor elements arranged in parallel to each other; a first conductor plate and a second conductor plate respectively bonded to an upper surface and a lower surface of the power semiconductor elements arranged in parallel to each other; a wiring substrate provided on the second conductor plate; and an electronic component mounted on the wiring substrate, the power semiconductor elements, the first conductor plate, the second conductor plate, the wiring substrate, and the electronic component being sealed with a sealing member. The first conductor plate positioned on the upper surface side of the wiring substrate has at least one of a recess and a through hole in a region facing with the electronic component on the wiring substrate.

### TECHNICAL FIELD

This invention relates to a semiconductor module, a power conversion device, and a method for manufacturing the semiconductor module.

### BACKGROUND ART

A power conversion device making use of switching of a power semiconductor element has a high conversion efficiency and is therefore used widely for consumers, vehicles, railways, transformation units, and the like. In recent years, due to a limitation in current that can be applied to a power semiconductor element, a plurality of power semiconductor elements is connected in parallel to each other to have an increased output corresponding to a large current. On the other hand, power semiconductor elements require therearound electronic components such as a gate resistor for adding charges necessary for driving to the gate of the power semiconductor elements and a chip capacitor for smoothing the surge at the time of switching the power semiconductor elements. In a semiconductor module obtained by sealing a plurality of power semiconductor elements, sealing of such electronic components is also required.

Patent Literature 1 discloses a power conversion device having a plurality of power semiconductor elements connected in parallel to each other.

### CITATION LIST

### Patent Literature

Patent Literature 1: Japanese Unexamined Patent Application Publication No. 2019-068534

### SUMMARY OF INVENTION

### Technical Problem

Sealing of electronic components together with a plurality of power semiconductor elements has such a problem that a space permitting a sealing member to flow therein becomes narrow to generate voids and the like, and the resulting semiconductor module has deteriorated reliability.

### Solution to Problem

A semiconductor module according to the present invention includes: a plurality of power semiconductor elements arranged in parallel to each other; a first conductor plate and a second conductor plate respectively bonded to an upper surface and a lower surface of the power semiconductor elements arranged in parallel to each other; a wiring substrate provided on the second conductor plate; and an electronic component mounted on the wiring substrate. The power semiconductor elements, the first conductor plate, the second conductor plate, the wiring substrate, and the electronic component are sealed with a sealing member. The first conductor plate positioned on the upper surface side of the wiring substrate has at least one of a recess and a through hole in a region facing with the electronic component on the wiring substrate.

### Advantageous Effects of Invention

According to the present invention, it is possible to provide a semiconductor module having high reliability by suppressing generation of voids or the like.

### BRIEF DESCRIPTION OF DRAWINGS

FIG. 1 is a plan view of an electric circuit body.

FIG. 2 is a cross-sectional view of the electric circuit body.

FIG. 3 is a plan view of a semiconductor module.

FIG. 4 is a plan view showing an inner structure of the semiconductor module.

FIGS. 5(a), 5(b), and 5(c) are each a cross-sectional view of the semiconductor module.

FIG. 6 is a cross-sectional view showing a step of manufacturing the semiconductor module.

FIGS. 7(a) and 7(b) are each a cross-sectional view showing a step of manufacturing a semiconductor module of Comparative Example.

FIGS. 8(a) and 8(b) are each a view showing a semiconductor module of Modification Example 1.

FIG. 9 is a cross-sectional view showing a step of manufacturing the semiconductor module 300 of Modification Example 1.

FIGS. 10(a), 10(b), and 10(c) are each a cross-sectional view showing a step of manufacturing a semiconductor module of Modification Example 2.

FIGS. 11(a), 11(b), and 11(c) are each an external-appearance perspective view showing a step of manufacturing a conductor plate on an emitter side.

FIGS. 12(a) and 12(b) are each a view showing the shape of a through hole.

FIG. 13 is a circuit diagram of the semiconductor module.

FIG. 14 is a circuit diagram of a power conversion device using the semiconductor module.

FIG. 15 is an external-appearance perspective view showing one example of a power conversion device.

FIG. 16 is a cross-sectional view of a power conversion device.

### DESCRIPTION OF EMBODIMENTS

Embodiments of the present invention will hereinafter be described referring to drawings. The following description and drawings are examples for describing the present invention and they have been simplified or partially omitted as needed for the purpose of clear description. The present invention can be implemented in other various embodiments. The number of each constituent may be singular or plural unless otherwise limited.

The position, size, shape, range, or the like of each constituent shown in the drawings sometimes does not represent the actual position, size, shape, range, or the like in order to facilitate the understanding of the invention. The present invention is therefore not necessarily limited to the position, size, shape, range, or the like disclosed in the drawings.

When there is a plurality of constituents having the same or similar function, they are sometimes described while assigning different subscripts to the same reference number. If these is no need to distinguish these constituents, they may be described without using a subscript.

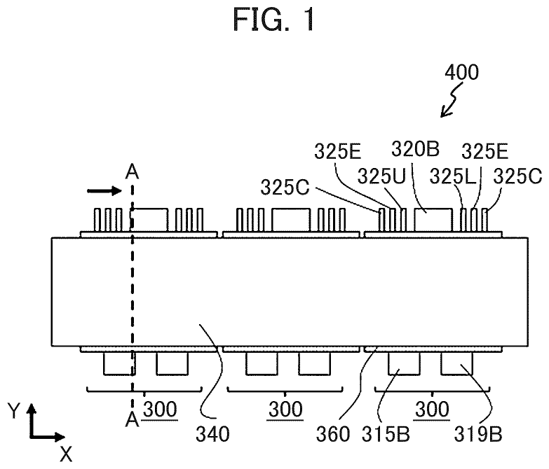

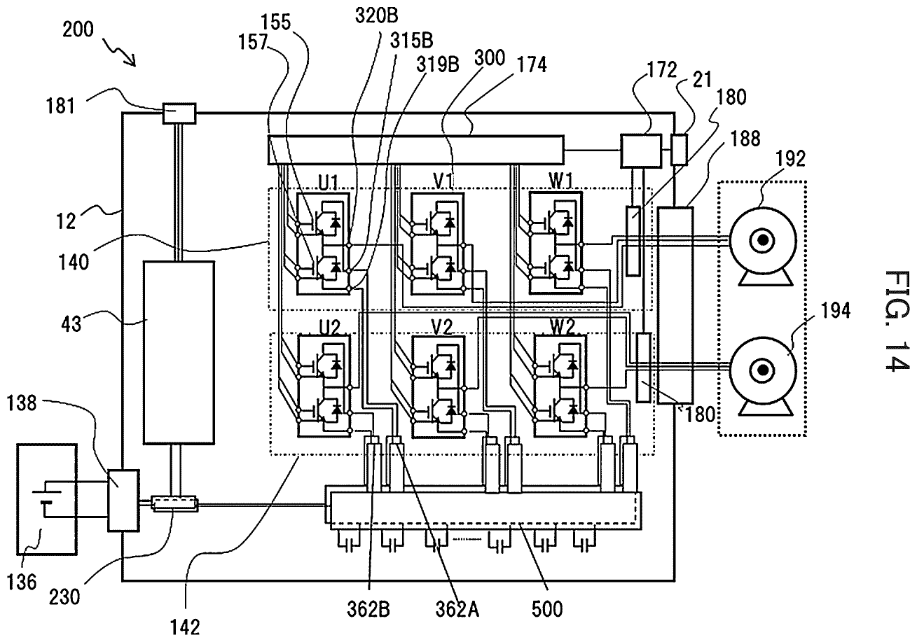

FIG. 1 is a plan view of an electric circuit body 400. The electric circuit body 400 has semiconductor modules 300 and a cooling member 340. It has three semiconductor modules 300. They have a function of performing the conversion between a direct current and an alternating current by means of a power semiconductor element. Since they generate heat when electricity is applied thereto, they are cooled by a refrigerant that flows in the cooling member 340. As the refrigerant, water, an antifreezing liquid obtained by mixing ethylene glycol in water, or the like can be used. The semiconductor modules 300 are each equipped with power terminals through which a large current flows, such as a positive electrode side terminal 315B and a negative electrode side terminal 319B each connected to a capacitor module 500 (refer to FIG. 14) of a DC circuit, and an AC-side terminal 320B connected to motor generators 192 and 194 (refer to FIG. 14) of an AC circuit. In addition, they are each equipped with signal terminals, which are used for controlling the semiconductor module 300, such as a lower arm gate terminal 325L, an emitter sense signal terminal 325E, a collector sense signal terminal 325C, and an upper arm gate terminal 325U.

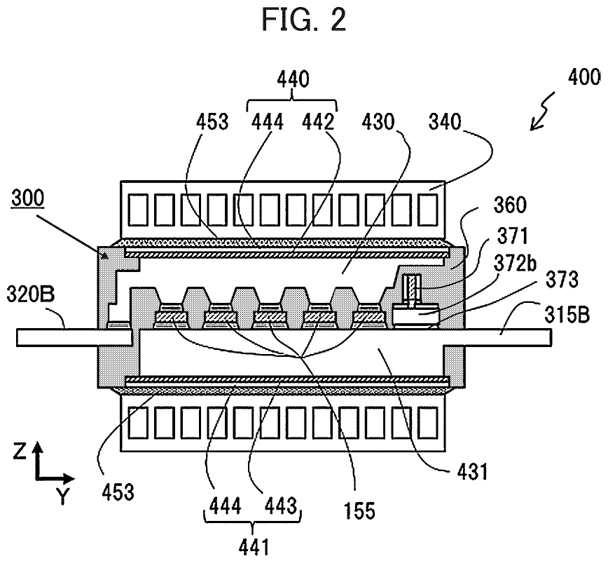

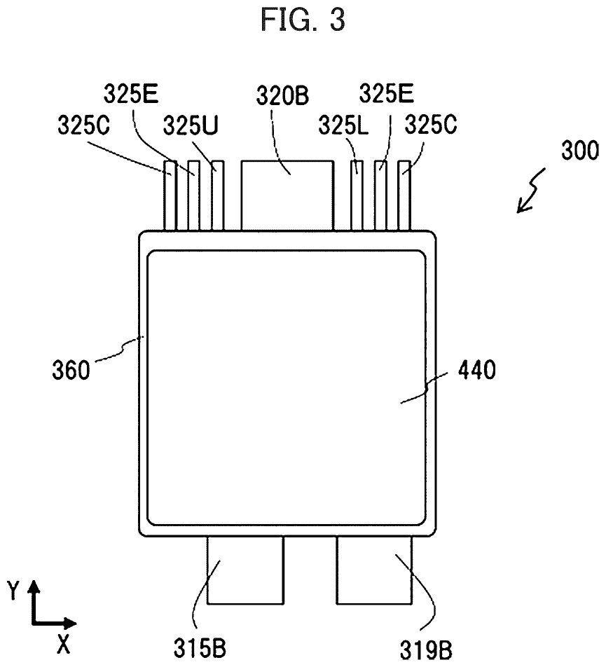

FIG. 2 is a cross-sectional view of the electric circuit body 400. It is a cross-sectional view taken along the line A-A shown in FIG. 1. FIG. 3 is a plan view of the semiconductor module 300. It shows one semiconductor module 300 mounted on the electric circuit body 400 shown in FIG. 1.

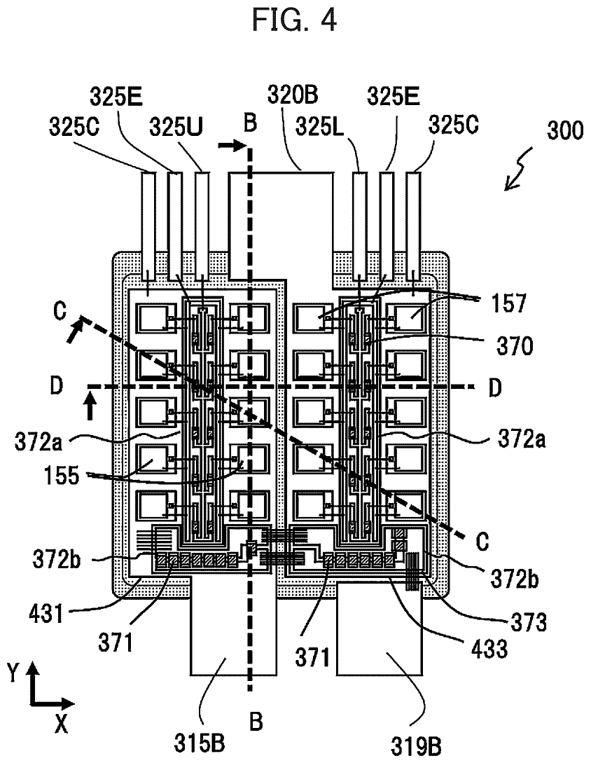

An upper arm circuit is formed by arranging five power semiconductor elements 155 (refer to FIG. 4) in two rows and connecting them in parallel to each other. As the power semiconductor elements 155, Si, SiC, GaN, GaO, C, and the like are usable. When a body diode of a power semiconductor element is used, a separately attached diode may be omitted. The power semiconductor element 155 is bonded, on the collector side thereof, to a second conductor plate 431. A bonding member used for this bonding may be either a solder or a sintered metal. The power semiconductor element 155 is bonded, on the emitter side thereof, to a first conductor plate 430.

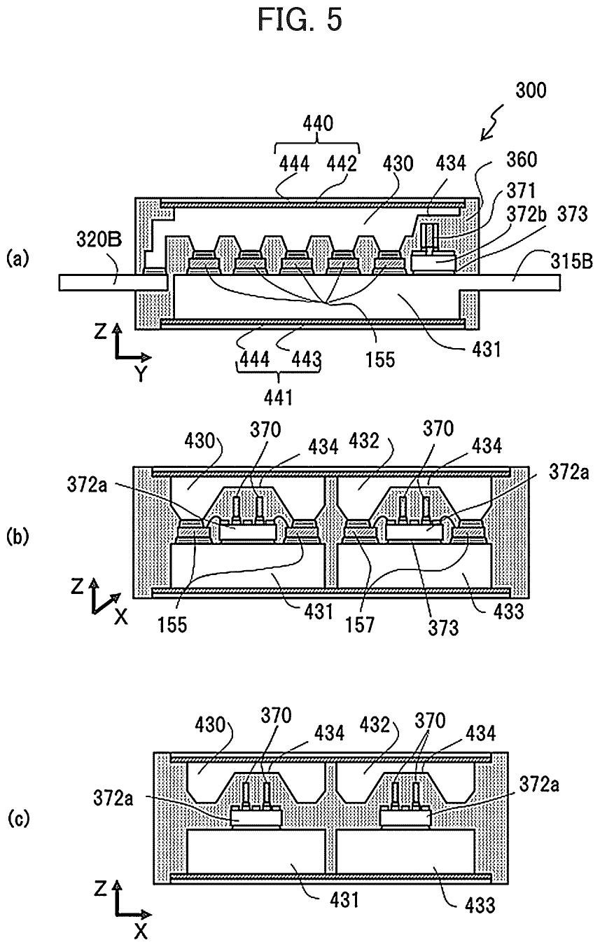

A lower arm circuit is formed by arranging five power semiconductor elements 157 (refer to FIG. 4) in two rows and connecting them in parallel to each other. The power semiconductor element 157 is bonded, on the collector side thereof, to a fourth conductor plate 433 (refer to FIG. 5(b)). The power semiconductor element 157 is bonded, on the emitter side thereof, to a third conductor plate 432 (refer to FIG. 5(b)).

The material of the conductor plates 430, 431, 432, and 433 is not particularly limited insofar as it has high electrical conductivity and thermal conductivity and it is desirably a copper-based or aluminum-based material. Such a material may be used singly but may be soldered or plated with Ni, Ag, or the like to have enhanced bondability with a sintered metal. The conductor plates 430, 431, 432, and 433 have a role of conducting a current and in addition, have a role as a heat conductive member for conducting the heat generated by the power semiconductor elements 155 and 157 to the cooling member 340. The conductor plates 430, 431, 432, and 433 and the cooling member 340 have therebetween insulating layers 442 and 443 (refer to FIG. 2) because they are different in potential. As the insulating layers 442 and 443, either a resin-based insulating layer or a ceramic-based insulating layer may be used. The ceramic-based insulating layer has the advantage of excellent thermal conductivity. On the other hand, the resin-based insulating layer has the advantage of excellent productivity because it is able to have adhesion properties and therefore can be contact-bonded to the conductor plates 430, 431, 432, and 433. The present embodiment shows one example of the resin-based insulating layer.

The insulating layers 442 and 443 are combined with a metal foil 444 to obtain sheet members 440 and 441 and the resulting sheet members on the side of the insulating layers 442 and 443 are contact-bonded to the conductor plates 430, 431, 432, and 433 to produce, with improved workability, an insulating sheet having adhesion properties on only one side. In addition, the metal foil 444 used on the side contiguous to the cooling member 340 can protect the insulating layers 442 and 443. Between the sheet members 440 and 441 and the cooling member 340, a heat conductive member 453 is provided to reduce a contact thermal resistance. The power semiconductor elements 155 and 157 and the conductor plates 430, 431, 432, and 433 are sealed by transfer molding with a sealing member 360 such as a sealing resin. The sheet members 440 and 441 may be prevented from peeling off from their end portion by burying the end portion of the sheet members 440 and 441 in the sealing member 360.

FIG. 4 is a plan view showing the inner structure of the semiconductor module 300. FIG. 4 is a view obtained by removing the first sheet member (emitter side) 440, the first conductor plate (the emitter side of the upper arm circuit) 430, and the third conductor plate (the emitter side of the lower arm circuit) from the plan view of the semiconductor module 300 of FIG. 3.

As shown in FIG. 4, the power semiconductor elements 155 constituting the upper arm circuit are arranged in two rows on the second conductor plate 431 and each row has five power semiconductor elements. Similarly, the power semiconductor elements 157 constituting the lower arm circuit are arranged in two rows on the fourth conductor plate 433 and each row has five power semiconductor elements. The parallelly-arranged rows of the power semiconductor elements 155 and 157 have therebetween a wiring substrate 372a on the conductor plates 431 and 433, respectively. The wiring substrate 372a has thereon a signal wiring for connecting the power semiconductor elements 155 and 157 to a signal terminal such as the lower arm gate terminal 325L, the emitter sense signal terminal 325E, the collector sense signal terminal 325C, and the upper arm gate terminal 325U. The signal wiring connected to the gate of the power semiconductor elements 155 and 157 has a chip resistor 370. By placing the wiring substrate 372a between the two rows of each of the power semiconductor elements 155 and 157, the wiring of the power semiconductor elements 155 and 157 on both sides can be routed using one wiring substrate 372a, making it possible to reduce the number and the area of the wiring substrate 372a and enhance the efficiency.

The conductor plates 431 and 433 have thereon, at the end portion of the conductor plates 431 and 433, a wiring substrate 372b via an adhesive 373. The wiring substrate 372b has thereon a signal wiring for connecting the power semiconductor elements 155 and 157 to a signal terminal and the signal terminal has a chip capacitor 371 thereon. When switching is performed at high speed by using a next-generation device such as SiC as the power semiconductor elements 155 and 157, a portion of a smoothing capacitor is placed as the chip capacitor 371 in the semiconductor module 300. In this case, the chip capacitor 371 placed in the semiconductor module 300 can lower the inductance. This makes it possible to smoothen the surge at the time of high-speed switching that cannot be accomplished by a smoothing capacitor provided outside the semiconductor module 300 and causing an increase in the inductance.

The description will be made with an example in which the chip resistor 370 or chip capacitor 371 are placed on the wiring substrates 372a and 372b, but other electronic components including the chip resistor 370 and the chip capacitor 371 may be placed. For example, an enhanced function may be achieved by mounting a trouble diagnostic IC or electronic component such as current sensor or temperature sensor on the wiring substrates 372a and 372b. Alternatively, the wiring substrate 372a or 372b may be a multilayer substrate obtained by sandwiching an insulating layer therein.

FIGS. 5(a), 5(b), and 5(c) are each a cross-sectional view of the semiconductor module 300. FIG. 5(a), FIG. 5(b), and FIG. 5(c) are cross-sectional views taken along the line B-B shown in FIG. 4, the line C-C shown in FIG. 4, and the line D-D shown in FIG. 4, respectively. These cross-sectional views show a semiconductor module having the first sheet member (on the emitter side) 440 and the first conductor plate (on the emitter side of the upper arm circuit) 430 that have been removed in FIG. 4.

As shown in FIG. 5(a), the wiring substrate 372b has thereon the chip capacitor 371. The conductor plate 430 positioned on the upper surface side of this wiring substrate 372b has a recess 434 in a region facing the chip capacitor 371 on the wiring substrate 372b.

As shown in FIG. 5(b), the wiring substrate 372a has thereon the chip resistor 370. The conductor plates 430 and 432 positioned on the upper surface side of the wiring substrate 372a have a recess 434 in a region facing the chip resistor 370 on the wiring substrate 372a.

As shown in FIG. 5(c), the conductor plates 430 and 432 positioned on the upper surface side of the wiring substrate 372a have a recess 434 in a region facing the chip resistor 370 on the wiring substrate 372a. The recess 434 is provided along an arranging direction of the power semiconductor elements 155 and 157. The wiring substrate 372a has a space on both sides thereof. In a transfer molding step, a sealing member is poured into the space and the recess 434 to fill them therewith. In this case, the recess 434 thus provided prevents the thus-poured sealing member from being disturbed by the electronic components placed on the wiring substrates 372a and 372b. Therefore, even when both the power semiconductor elements and the electronic components are sealed together, it does not narrow the space in which the sealing member flows and does not generate voids and the like and therefore, the semiconductor module 300 thus obtained does not have deteriorated reliability. In addition, the semiconductor module 300 having high reliability can be provided without increasing the thickness of the semiconductor module 300.

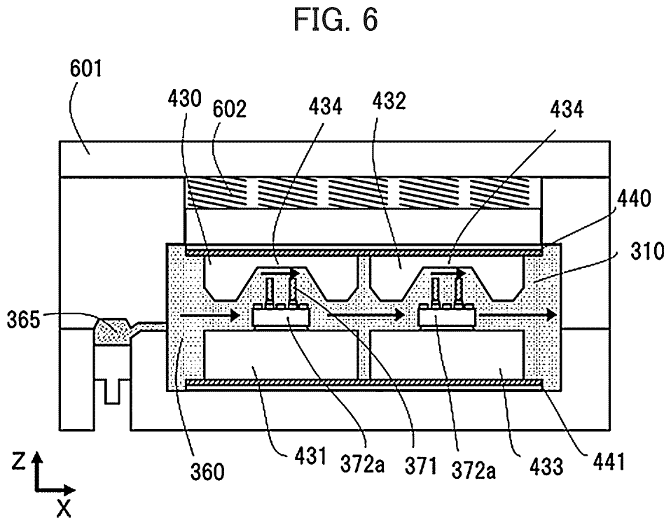

FIG. 6 is a cross-sectional view showing a step of manufacturing the semiconductor module 300. Similar to FIG. 5(c), it is a cross-sectional view taken along the line D-D shown in FIG. 4. In a mold in a transfer molding device 601, a semiconductor module 300 (which will hereinafter be called “circuit body 310”) which has not been sealed yet with the sealing member 360. This circuit body 310 includes the power semiconductor elements 155 and 157, the conductor plates 431 and 433 bonded to the upper surface and the lower surface of the power semiconductor elements 155 and 157, the wiring substrates 372a and 372b provided on the conductor plates 431 and 433, and electronic components such as the chip resistor 370 and the chip capacitor 371 which are mounted on the wiring substrates 372a and 372b.

The transfer molding device 601 is equipped with a spring 602, a mechanism for vacuum adsorbing the sheet members 440 and 441 to the mold, and a vacuum deaeration mechanism. The transfer molding device 601 retains the sheet members 440 and 441 in the mold, which has been heated in advance to a constant-temperature state of 175° C., by vacuum adsorption. Next, from the state where the sheet members 440 and 441 are separated from the circuit body 310, upper and lower molds are brought close to each other and only a packing placed around the unillustrated upper and lower molds is brought into contact. Then, vacuum evacuation of a mold cavity is performed. After the vacuum evacuation to a predetermined air pressure or less is completed, the packing is pressed further to completely clamp the upper and lower molds. At this time, the sheet members 440 and 441 are brought into contact with the circuit body 310. Since the sheet members 440 and 441 and the circuit body 310 are brought into contact with each other under a vacuum state and they are bonded firmly by a pressure applied by the spring 602, they can be bonded firmly without dragging a void therein. Then, in a transfer molding step, the sealing member 360 is poured into a mold cavity from an inlet 365.

As already described, the conductor plates 430 and 432 have therein the recess 434. For example, between the electronic component and the conductor plates 430 and 432, a space of 240 μm or more is set in order to completely fill the sealing member 360 also onto the electronic component in the transfer molding step. A filling member with which the sealing member 360 is filled has a particle size of 80 μm or less but when the filling member having a particle size less than three times the maximum particle size is used, it may allow the uneven distribution of the filling member at the flowing time and deteriorate the resin strength. Setting the space between the electronic component and the conductor plates 430 and 432 at 240 μm or more secures the resin strength of a portion sealed in the recess 434 and is effective for enhancing the reliability against a thermal stress such as temperature change. In addition, contact-bonding of the sheet members 440 and 441 including the insulating layers 442 and 443 in the transfer molding step contributes to productivity improvement.

In a curing step subsequent thereto, the semiconductor module 300 sealed with the sealing member 360 is taken out from the transfer molding device 601, cooled at normal temperature, and then, cured for 2 hours or more.

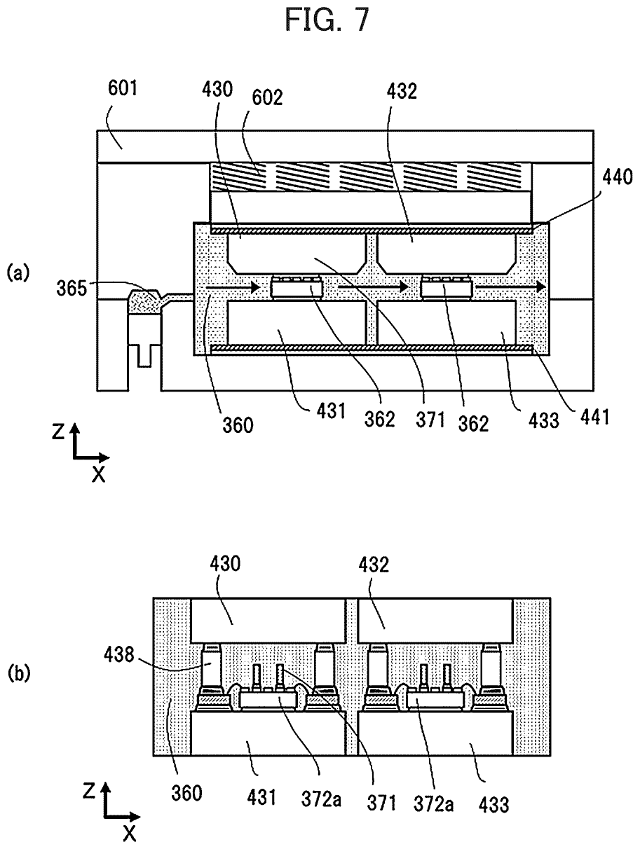

FIGS. 7(a) and 7(b) are cross-sectional views showing a step of manufacturing Comparative Example. This Comparative Example is shown for comparing an example not using the present embodiment with the present embodiment. The description will be made simply by assigning the same reference number to the same portion as that shown in FIG. 6.

FIG. 7(a) shows an example in which the conductor plates 430 and 432 have no recess 434 therein. As shown in FIG. 7(a), it is difficult to mount electronic components on the wiring substrate 362 when the conductor plates 430 and 432 have no recess 434 therein. In addition, even if the wiring substrate 362 is placed, the space between the wiring substrate 362 and the conductor plates 430 and 432 becomes less than 240 μm, and an unfilled portion of the sealing member 360 may occurs or filled portion with the sealing member 360 may have insufficient resin strength.

FIG. 7(b) shows an example in which a space is secured by inserting a spacer 438 between the conductor plates 430 and 432 on the emitter side and the conductor plates 431 and 433 on the collector side. The transfer molding device 601 is not shown in this figure. In this case, although the sealing member 360 has improved fluidity, the spacer 438 becomes high, causing deterioration in the heat conduction to the conductor plates 430 and 432 on the emitter side and lowering in the heat release properties.

In the present embodiment, compared with such Comparative Example, by forming the recess 434 in the conductor plates 430 and 432 on the emitter side to enhance the fluidity of the sealing member 360, it is possible to mount electronic components on the wiring substrate 362, keep the resin strength of a portion filled with the sealing member 360, and maintain the heat release properties.

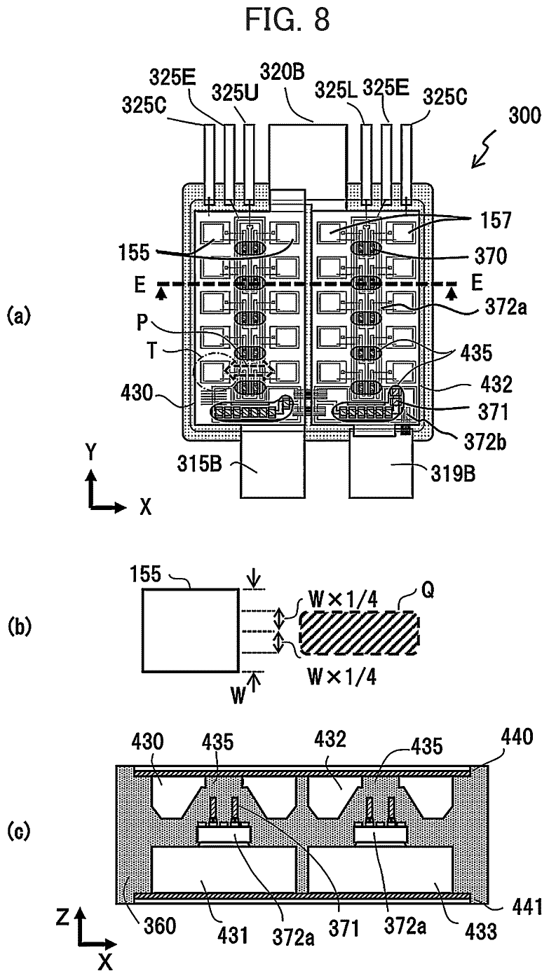

FIGS. 8(a) and 8(b) are views showing a semiconductor module 300 of Modification Example 1. FIG. 8(a) is a semi-perspective view showing the inner structure of the semiconductor module 300. This FIG. 8(a) is a view obtained by removing the first sheet member (on the emitter side) 440 from the plan view of the semiconductor module 300 of FIG. 3, that is, a view obtained by bonding the first conductor plate (on the emitter side of the upper arm circuit) 430 and the third conductor plate (on the emitter side of the lower arm circuit) 432 to the power semiconductor elements 155 and 157 of FIG. 4. FIG. 8(b) is an enlarged view of a region T of FIG. 8(a). FIG. 8c is a cross-sectional view taken along a line E-E of FIG. 8(a). The description will be made simply by assigning the same reference number to the same portion as that shown in FIG. 4.

As shown in FIG. 8(a), the conductor plates 430 and 432 positioned on the upper surface side of the wiring substrates 372a and 372b have a through hole 435 in a region facing the electronic components (chip resistor 370 and chip capacitor 371) on the wiring substrates 372a and 372b.

The through hole thus provided prevents the poured sealing member from being blocked by the electronic components placed on the wiring substrates 372a and 372b in the transfer molding step. This makes it possible to provide, when the power semiconductor elements and the electronic components are sealed together, a highly-reliable semiconductor module 300 without deteriorating the reliability of the semiconductor module 300 due to narrowing of a space in which the sealing member flows and due to generation of voids and the like and without increasing the thickness of the semiconductor module 300.

A plurality of through holes 435, which is provided in a region facing the chip resistor 370, is provided along the arranging direction of the power semiconductor elements 155 and 157 at a position which does not overlap with a straight-line path P for connection between the power semiconductor elements 155 and 157 facing with each other with the wiring substrate 372a therebetween. Forming the through holes 435 at a position which does not overlap with the straight-line path P connecting the power semiconductor elements 155 and 157 and the power semiconductor elements 155 and 157 with the shortest distance prevents a leakage current from by-passing the through hole 435 and thereby prevents an increase in inductance. More specifically, the straight-line path P is a region defined by the width W of the power semiconductor element 155 or 157 and a distance thereof. The through hole 435 is provided so as not to enter this region. A straight-line path Q is a region defined by a range of +W×¼ and −W×¼ (a range of W× 2/4 of the center portion of the width W) from the center line of the width W of the power semiconductor elements 155 or 157 facing with each other with the wiring substrate 372a or 372b and a distance of them. The through hole 435 is provided so that it does not enter at least this straight-line path Q.

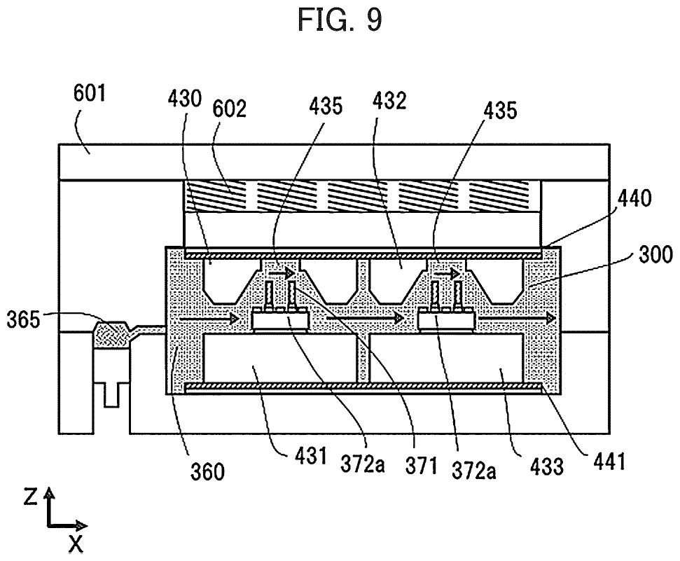

FIG. 9 is a cross-sectional view showing a step of manufacturing a semiconductor module 300 of Modification Example 1. It will be described simply by assigning the same reference number to the same portion as that shown in FIG. 6. As shown in FIG. 8(a), the conductor plates 430 and 432 each have therein a through hole 435.

First, in a mold in the transfer molding device 601, a semiconductor module 300 (a circuit body 310 having sheet members 440 and 441 therein) before being sealed with a sealing member 360 is placed. This semiconductor module 300 includes power semiconductor elements 155 and 157, conductor plates 431 and 433 bonded respectively to the upper surface and the lower surface of the power semiconductor elements 155 and 157, sheet members 440 and 441 that sandwich, by both surfaces thereof, the outer surface of the conductor plates 431 and 433 and the conductor plates 430 and 432, wiring substrates 372a and 372b provided on the conductor plates 431 and 433, wiring substrates 372a and 372b provided on the conductor plates 431 and 433, and electronic components such as a chip resistor 370 or a chip capacitor 371 mounted on the wiring substrates 372a and 372b.

The transfer molding device 601 is equipped with a spring 602, a mechanism for vacuum adsorbing the sheet members 440 and 441 to a mold, and a vacuum deaeration mechanism. The transfer molding device 601 retains the sheet members 440 and 441 by vacuum adsorption in the mold heated in advance to a constant-temperature state of 175° C. Next, from a state in which the sheet members 440 and 441 and the circuit body 310 are separated from each other, the upper and lower molds are brought close contact, and only packing portions provided around the upper and lower molds which are not shown in this figure are brought into contact. Then, a mold cavity is vacuum evacuated. After vacuum evacuation is completed so as to adjust the pressure to not more than a predetermined air pressure, the packing portions are pressed further to clamp the upper and lower molds completely. At this time, the sheet members 440 and 441 are brought into contact with the circuit body 310. Since the sheet members 440 and 441 and the circuit body 310 are brought into contact under a vacuum condition and they are adhered closely by a pressure applied by the spring 602, they can be adhered closely without enclosing voids.

In a transfer molding step, the sealing member 360 is poured into a mold cavity from an inlet 361. The conductor plates 430 and 432 on the emitter side have a through hole 435 so that the fluidity of the sealing member 360 is not damaged and the heat release properties of the semiconductor module can be maintained even if the wiring substrate 362 has a tall electronic component thereon.

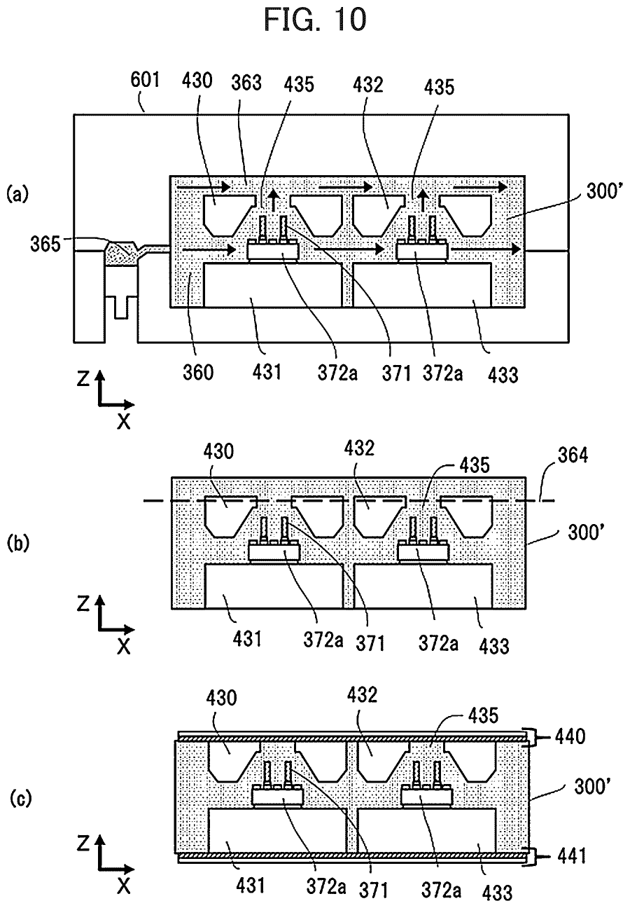

FIGS. 10(a), 10(b), and 10(c) are each a cross-sectional view showing a step of manufacturing a semiconductor module 300 of Modification Example 2. The description will be made simply by assigning the same reference number to the same portion as that shown in FIG. 9.

In the mold in the transfer molding device 601, a semiconductor module 300′ before being sealed with the sealing member 360 is placed. This semiconductor module 300′ has not yet been provided with the sheet members 440 and 441. This means that the semiconductor module 300′ includes power semiconductor elements 155 and 157, conductor plates 431 and 433 bonded to the upper surface and the lower surface of the power semiconductor elements 155 and 157, wiring substrates 372a and 372b provided on the conductor plates 431 and 433, wiring substrates 372a and 372b provided on the conductor plates 431 and 433, and electronic components such as chip resistor 370 and chip capacitor 371 mounted on the wiring substrates 372a and 372b. An over-mold portion 363 which is a space is formed between the mold and the conductor plates 431 and 433 in the transfer molding device 601.

In the transfer molding step, the sealing member 360 is poured into a mold cavity from the inlet 361. Since the sealing member 360 flows in the over-mold portion 363 and the through hole 435, even mounting of a tall electronic component on the wiring substrate 362 does not damage the fluidity of the sealing member 360 and the sealing member 360 has drastically improved filling properties. The semiconductor module can therefore maintain its heat release properties.

FIG. 10(b) is a grinding step and in this step, the semiconductor module 300′ taken out after the sealing member 360 is cured is ground up to a ground surface 364 from which the conductor plates 430 and 432 on the emitter side are exposed.

FIG. 10(c) is a contact-bonding step and after the grinding step, the sheet members 440 and 441 are contact-bonded to the both surfaces of the semiconductor module 300′.

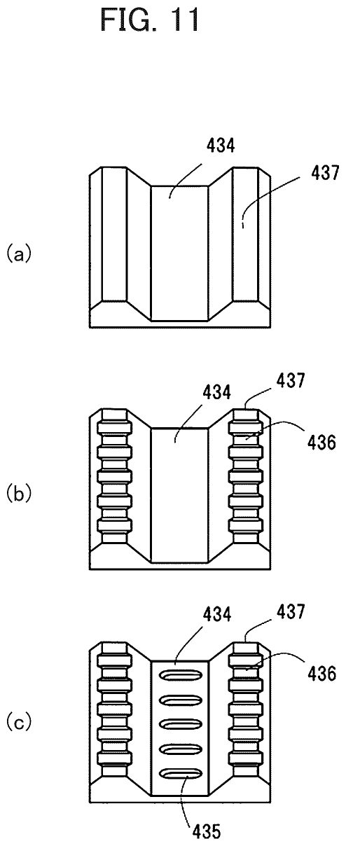

FIGS. 11(a), 11(b), and 11(c) are each an external-appearance perspective view showing a step of manufacturing conductor plates 430 and 432 on the emitter side.

FIG. 11(a) is a step of manufacturing a copper plate. A recess 434 is formed in the copper plate to be used as the conductor plates 430 and 432. A protruding portion 437 is formed on both sides of the recess 434 in the direction along the groove thereof. Manufacturing the recess 434 and the protruding portion 437 as a drawing material contributes to improved productivity.

FIG. 11(b) is a protrusion formation step. Protrusions 436 are formed by denting the protruding portion 437 by a press at predetermined intervals. The recess 434 is provided along an arranging direction of the power semiconductor elements 155 and 157. A wiring substrate 372a corresponding to the recess 434 is placed. The protrusions 436 are therefore provided at predetermined intervals in an arranging direction of the power semiconductor elements 155 and 157 on both sides of the wiring substrate 372a. As a result, the sealing member is also poured between one protrusion 436 and another protrusion 436 in the transfer molding step to suppress void generation and the resulting semiconductor module 300 therefore has enhanced reliability.

FIG. 11(c) is a through hole formation step. Through holes 435 are formed by punching the recess 434 at predetermined intervals. A plurality of through holes 435 is provided along the arranging direction of the power semiconductor elements 155 and 157 at a position not overlapping with straight-line paths P and Q that connect the power semiconductor elements 155 and 157 facing with each other with the wiring substrate 372a therebetween.

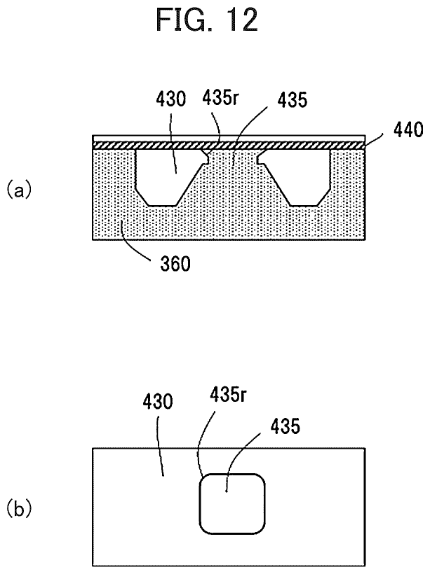

FIGS. 12(a) and 12(b) are each a view showing the shape of the through holes 435. FIG. 12(a) is a cross-sectional view and FIG. 12(b) is a plan view thereof in a state where the sheet member 440 is removed.

As shown in FIG. 12(a), by subjecting the through hole 435 of the conductor plate 430 on the emitter side to surface curving or providing it with R chamfering 435r, the stress of a contact portion between the conductor plate 430 and the sheet member 440 is relaxed and the resulting semiconductor module 300 has improved reliability. As shown in FIG. 12(b), also when the conductor plate 430 is viewed from the upper surface, the stress of a contact portion between the conductor plate 430 and the sheet member 440 is relaxed and the resulting semiconductor module has improved reliability by providing the through hole with the R or chamfering 435r.

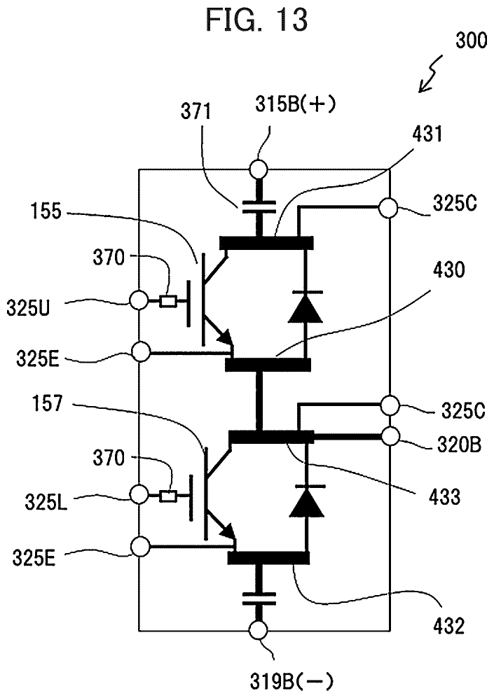

FIG. 13 is a circuit diagram of the semiconductor module 300. The terminal 315B outputs from the collector side of the upper arm circuit and is connected to the positive electrode side of a battery or a capacitor. The terminal 325U is output from the gate and emitter sense of the power semiconductor element 155 of the upper arm circuit. The terminal 319B is output from the emitter side of the lower arm circuit and is connected to the negative electrode side of the battery or capacitor, or GND. The terminal 325L is output from the gate and emitter sense of the power semiconductor element 157 of the lower arm circuit. A terminal 320B is output from the collector side of the lower arm circuit and is connected to a motor. In the case of neutral point grounding, the lower arm circuit is connected not to GND but to the negative electrode side of the capacitor. The chip resistor 370 is provided between the gate terminal 325U and the power semiconductor element 155 or between the gate terminal 325L and the power semiconductor element 157 to stabilize charges to be applied to a gate. The terminal 325C is a terminal of a collector sense signal and the terminal 325E is a terminal of an emitter sense signal.

The chip capacitor 371 is provided between the second conductor plate 431 and the positive electrode side terminal 315B or between the third conductor plate 432 and the negative electrode side terminal 319B to smoothen the surge at the time of high-speed switching.

In FIG. 13, the power semiconductor elements 155 and 157 are each represented by one reference number, but as described referring to FIG. 3, the semiconductor elements 155 are arranged in two rows and one row has five elements. Similarly, the power semiconductor elements 157 are arranged in two rows and each row has five elements. This means that ten power semiconductor elements 155 and 157 are used while arranging them in parallel to each other in order to increase an applicable current and thereby to have an enhanced output. The above-described number of the power semiconductor elements to be used in parallel is one example and power semiconductor elements may be used in multi-parallel, depending on a required output.

When the power semiconductor elements 155 and 157 are used in multi-parallel, it is desired to provide a gate resistor per elements arranged in multi-parallel in order to prevent malfunction of the power semiconductor elements 155 and 157. The semiconductor module 300 has therein a wiring substrate 372a having, as this gate resistor, a chip resistor 370 mounted thereon.

The semiconductor module 300 of the present embodiment has a 2-in-1 structure obtained by integrating two arm circuits which are one upper arm circuit and one lower arm circuit, with one semiconductor module 300. In addition to the 2-in-1 structure, it may also have a 3-in-1 structure obtained by integrating two arm circuits which are one upper arm circuit and one lower arm circuit, and either one of the upper arm circuit or the lower arm circuit with one semiconductor module 300; a 4-in-1 structure obtained by integrating four arm circuits, which are upper arm circuits and lower arm circuits, with one semiconductor module 300, a six-in-1 structure obtained by integrating six arm circuits, which are upper arm circuits and lower arm circuits, with one semiconductor module 300, or the like.

FIG. 14 is a circuit diagram of a power conversion device 200 using the semiconductor module 300.

The power conversion device 200 is equipped with inverter circuit units 140 and 142, an inverter circuit unit 43 for auxiliary machine, and the capacitor module 500. The inverter circuit units 140 and 142 are equipped with a plurality of semiconductor modules 300 and they are connected into a three-phase bridge circuit. When a current capacity is large, further semiconductor modules 300 are connected in parallel and by carrying out parallel connection for each phase of the three-phase inverter circuit, it is possible to cope with an increase in current capacity. In addition, as described in the present embodiment, it is also possible to cope with an increase in current capacity by connecting, in parallel, active elements 155 and 157 or diodes 156 and 158 which are power semiconductor elements built in the semiconductor module 300.

The inverter circuit unit 140 and the inverter circuit unit 142 have the same basic circuit constitution and their controlling method or operation is essentially the same. The outline of the circuit-like operation of the inverter circuit unit 140 or the like is known so that a detailed description on it is omitted here.

As described above, the upper arm circuit is equipped with, as a power semiconductor element for switching, an active element 155 for upper arm and a diode 156 for upper arm, whereas the lower arm circuit is equipped with, as a power semiconductor element for switching, an active element 157 for lower arm and a diode 158 for lower arm. The active elements 155 and 157 receive a drive signal output from one or the other one of two driver circuits constituting driver circuits 174, perform switching operation, and then convert DC power supplied from the battery 136 to three-phase AC power.

As the active element, MOSFET (metal oxide semiconductor field effect transistor) may be used and in this case, the diode 156 for upper arm and the diode 158 for lower arm become unnecessary.

The positive-side terminal 315B and the negative-side terminal 319B of each of the upper and lower arm series circuits are connected, respectively, to DC terminals for the capacitor connection of the capacitor module 500. AC power is generated at each of the connection portions of the upper arm circuit and the lower arm circuit and the connection portions of the upper arm circuit and the lower arm circuit of the upper and lower arm series circuits are connected to the AC-side terminals 320B of the semiconductor modules 300, respectively. The AC-side terminals 320B of the semiconductor modules 300 of each phase are connected to an AC output terminal of the power conversion device 200 and the AC power thus generated is supplied to a stator winding of the motor generator 192 or 194.

The control circuit 172 forms, based on the information input from a control device on a vehicle side or a sensor (for example, current sensor 180), a timing signal for controlling the switching timing of the active element 155 for upper arm and the active element 157 for lower arm. The driver circuit 174 forms, based on the timing signal output from the control circuit 172, a drive signal for causing switching operation of the active element 155 for upper arm and the active element 157 for lower arm. Indicated by 181, 182, and 188 are connectors.

The upper and lower arm series circuits include a temperature sensor not shown and temperature information of the upper and lower arm series circuits are input into a microcomputer. In addition, voltage information on the DC positive-electrode side of the upper and lower arm series circuits are input into the microcomputer. Based on such information, the microcomputer detects overtemperature and overvoltage and when the overtemperature or overvoltage is detected, the switching operation of all the active elements 155 for upper arm and active elements 157 for lower arm is stopped to protect the upper and lower arm series circuits from overtemperature or overvoltage.

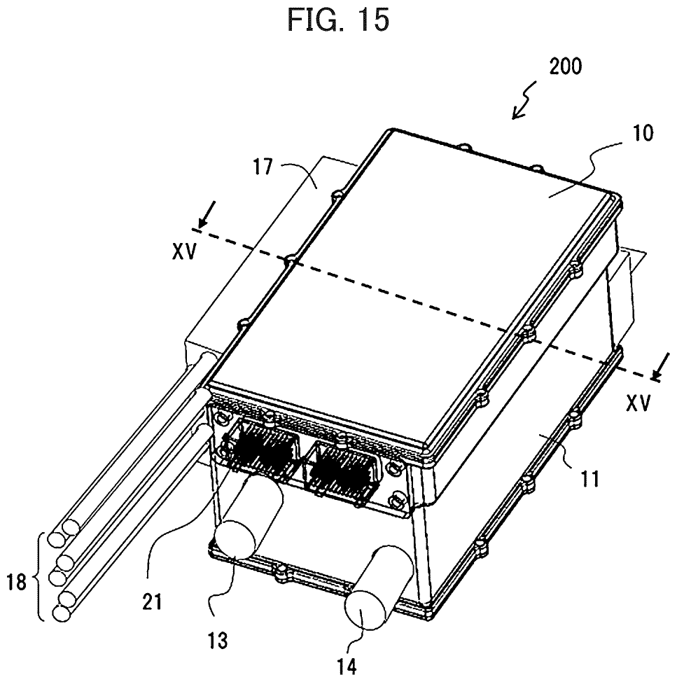

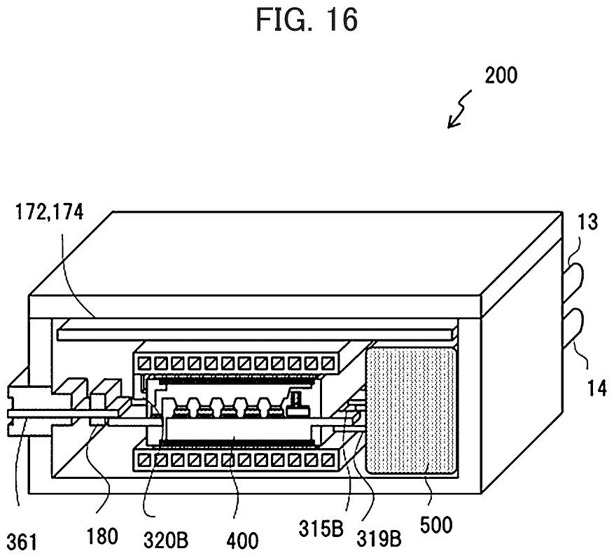

FIG. 15 is an external-appearance perspective view showing one example of the power conversion device 200 shown in FIG. 14 and FIG. 16 is a XV-XV cross-sectional view of the power conversion device 200 shown in FIG. 15.

The power conversion device 200 is comprised of a lower case 11 and an upper case 10 and is equipped with a chassis having almost a rectangular parallelopiped shape. The chassis has therein an electric circuit body 400, a capacitor module 500, and the like. The electric circuit body 400 has a cooling channel and from one side surface of the chassis 12, a cooling water inlet tube 13 and a cooling water outlet tube 14 communicated with the cooling channel are protruded. As shown in FIG. 15, the lower case 11 is opened on the upper side (Z direction) and the upper case 10 is attached to the lower case 11 while blocking the opening of the lower case 11. The upper case 10 and the lower case 11 are each made of an aluminum alloy or the like and are fixed while hermetically sealing against the outside. The upper case 10 and the lower case 11 may be formed as one body. The chassis 12 has a simple rectangular parallelopiped shape so that it can be installed easily to a vehicle or the like and in addition, can be produced easily.

The chassis 12 has a connector 17 attached thereto on one side surface thereof in a longer direction and this connector 17 has an AC terminal connected thereto. A connector 21 is provided on the surface from which the cooling water inlet tube 13 and the cooling water outlet tube 14 are derived.

As shown in FIG. 16, a chassis 12 has the electric circuit body 400 housed therein. Above the electric circuit body 400, the control circuit 172 and the driver circuit 174 are arranged, and the electric circuit body 400 has the capacitor module 500 housed therein on the DC terminal side. Since the capacitor module 500 is placed at a height equal to that of the electric circuit body 400, the power conversion device 200 can have a decreased thickness, leading to improved installation freedom. The AC-side terminal 320B of the electric circuit body 400 penetrates through the current sensor 180 and is bonded to a bus bar 361. The positive-side terminal 315B and the negative-side terminal 319B, which are DC terminals of the semiconductor module 300, are bonded to positive and negative electrode terminals 362A and 362B of the capacitor module 500, respectively.

According to the embodiment described above, the following operation and effects can be obtained.

(1) The semiconductor modules 300 and 300′ are equipped with a plurality of the power semiconductor elements 155 and 157 arranged in parallel to each other, the conductor plates 430 and 432 and the conductor plates 431 and 433 bonded respectively to the upper surface and lower surface of the power semiconductor elements 155 and 157 arranged in parallel to each other, the wiring substrates 372a and 372b provided on the conductor plates 431 and 433, and electronic components 370 and 371 mounted on the wiring substrates 372a and 372b; and have the power semiconductor elements 155 and 157, the conductor plates 430 and 432, the conductor plates 431 and 433, the wiring substrates 372a and 372b, and the electronic components 370 and 371 sealed with the sealing member. The conductor plates 430 and 432 positioned on the upper surface side of the wiring substrates 372a and 372b have at least one of the recess 434 and the through hole 435 in a region facing with the electronic components 370 and 371 on the wiring substrates 372a and 372b. Such a constitution makes it possible to provide a highly reliable semiconductor module suppressed in generation of voids and the like.

(2) A method for manufacturing the semiconductor modules 300 and 300′, which are equipped with a plurality of the power semiconductor elements 155 and 157 arranged in parallel to each other, the conductor plates 430 and 432 and the conductor plates 431 and 433 bonded respectively to the upper surface and lower surface of the power semiconductor elements 155 and 157 arranged in parallel to each other, the wiring substrates 372a and 372b provided on the conductor plates 431 and 433, and the electronic components 370 and 371 mounted on the wiring substrates 372a and 372b; and have the power semiconductor elements 155 and 157, the conductor plates 430 and 432, the conductor plates 431 and 433, the wiring substrates 372a and 372b, and the electronic components 370 and 371 sealed with the sealing member 360, includes a step of sealing by pouring the sealing member 360 into the recess 434 or through hole 435 formed in a region which is formed in the conductor plates 430 and 432 positioned on the upper surface side of the wiring substrates 372a and 372b and faces the electronic components 370 and 371 on the wiring substrates 372 and 372b. This method makes it possible to provide a highly reliable semiconductor module suppressed in generation of voids and the like.

The present invention is not limited to the above-described embodiment and another embodiment possible in the scope of the technical concept of the present invention may be embraced in the scope of the present invention insofar as it does not damage the feature of the present invention. In addition, the above-described embodiment and a plurality of modification examples may be used in combination.

### DESCRIPTION OF THE REFERENCE NUMBERS

11: Lower case, 13: Cooling water inlet tube, 14: Cooling water outlet tube, 17: Connector, 18: AC terminal, 21: Connector, 43, 140, 142: Inverter circuit unit, 155, 157: Power semiconductor element, 172: Control circuit, 174: Driver circuit, 180: Current sensor, 181, 182, 188: Connector, 192, 194: Motor generator, 200: Power conversion device, 300, 300′: Semiconductor module, 315B: Positive-side terminal, 319B: Negative-side terminal, 320B: AC-side terminal, 325: Signal terminal, 325C: Collector sense terminal, 325L: Lower arm gate terminal, 325E: Emitter sense terminal, 325U: Upper arm gate terminal, 340: Cooling member, 360: Sealing member, 361: Inlet, 362: Wiring substrate, 363: Over mold portion, 364: Ground surface, 370: Chip resistor, 371: Chip capacitor, 372a, 372b: Wiring substrate, 373: Adhesive, 400: Electric circuit body, 420: Conductor plate, 430: First conductor plate (upper arm circuit emitter side), 431: Second conductor plate (upper arm circuit collector side), 432: Third conductor plate (lower arm circuit emitter side), 433: Fourth conductor plate (lower arm circuit collector side), 434: Recess, 435: Through hole, 436: Protrusion, 440: First sheet member (emitter side), 441: Second sheet member (collector side), 442: First insulating layer (emitter side), 443: second insulating layer (collector side), 444: Metal foil, 453: Heat conductive member, 500: Capacitor module, 601: Transfer molding device, 602: Spring.

1. A semiconductor module comprising:
a plurality of power semiconductor elements arranged in parallel to each other;
a first conductor plate and a second conductor plate respectively bonded to an upper surface and a lower surface of the power semiconductor elements arranged in parallel to each other;
a wiring substrate provided on the second conductor plate; and
an electronic component mounted on the wiring substrate,
the power semiconductor elements, the first conductor plate, the second conductor plate, the wiring substrate, and the electronic component being sealed with a sealing member,
wherein the first conductor plate positioned on the upper surface side of the wiring substrate has at least one of a recess and a through hole in a region facing with the electronic component on the wiring substrate.

2. The semiconductor module according to claim 1,
wherein the recess is provided along an arranging direction of the power semiconductor elements.

3. The semiconductor module according to claim 1,
wherein a plurality of the through holes is provided at a position that does not overlap with a straight-line path that connects the power semiconductor elements facing with each other with the wiring substrate therebetween and is along an arranging direction of the power semiconductor elements.

4. The semiconductor module according to claim 3,
wherein the straight-line path is, supposing that W represents a width of the power semiconductor elements facing with each other with the wiring substrate therebetween, a range including W× 2/4 at the center portion of the width W.

5. The semiconductor module according to claim 1,
wherein the wiring substrate is provided between rows of the power semiconductor elements arranged in parallel to each other, and
the electronic component is a chip resistor.

6. The semiconductor module according to claim 1,
wherein the wiring substrate is provided at an end portion of the second conductor plate, and
the electronic component is a chip capacitor.

7. The semiconductor module according to claim 1, further comprising respective insulating-layer-containing sheet members contact-bonded to a side of the first conductor plate on a side opposite to the power semiconductor elements and to a side of the second conductor plate on a side opposite to the power semiconductor elements.

8. A power conversion device, comprising the semiconductor module as claimed in claim 1 and converting DC power to AC power.

9. A method for manufacturing a semiconductor module including a plurality of power semiconductor elements arranged in parallel to each other, a first conductor plate and a second conductor plate respectively bonded to an upper surface and a lower surface of the power semiconductor elements arranged in parallel to each other, a wiring substrate provided on the second conductor plate, and an electronic component mounted on the wiring substrate; the power semiconductor elements, the first conductor plate, the second conductor plate, the wiring substrate, and the electronic component being sealed with a sealing member, the method comprising,
a step of sealing by pouring the sealing member into a recess or through hole formed in a region facing with the electronic component on the wiring substrate, in the first conductor plate positioned on an upper surface side of the wiring substrate.
